(19) United States
(12) Patent Application Publication
(10) Pub. No.: US 2002/0079787 A1
(43) Pub. Date: Jun. 27, 2002

(54) Method of mounting a piezoelectric device directly to a printed circuit board

(76) Inventors: Kenneth Pohl, Albuquerque, NM (US); Gary L. Vaughn, Albuquerque, NM (US)

Correspondence Address: Steven D. Weseman, CTS Wireless Components, 171 Covington Drive, Bloomingdale, IL, 60108, US

(21) Appl. No.: 09/747,130

(22) Filed: Dec. 21, 2000

(51) Int. Cl. H01L 41/04

(52) U.S. Cl. 310/348; 310/352

(57) ABSTRACT

A method for flexible mounting piezoelectric devices at a spaced distance from a PC board by conductive adhesive so as to provide support to the device sufficient to withstand 50 g on three axes for 11 ms with minimal adverse effect on the operation and performance of the assembled structure. Also disclosed is a piezoelectric device flexibly mounted at a spaced distance from a PC board by conductive adhesive so as to provide support to the device sufficient to withstand 50 g on three axes for 11 ms with minimal adverse effect on the operation and performance of the device.

### TECHNICAL FIELD

The present invention relates to mounting piezoelectric devices. More particularly the present invention relates to mounting a piezoelectric transformer so as to withstand a shock of at least 50 g with minimum adverse effect on the device.

### BACKGROUND OF THE INVENTION

The miniaturization of circuits and components remains a top priority in most electronic industries. The miniaturization of solid-state components and combination-type circuitry chips, such as central processor units, digital signal processors, memory, etc., has been so successful that the packaging and electrical connections for access to such small devices has become one of the major roadblocks for further miniaturization. One of the packaging problems for some types of miniaturization circuits, such as for piezoelectric devices, is how to both support the piezoelectric device and make electrical connections without adversely affecting the operation and performance.

Prior art mounting techniques often included the use of silicon-type adhesives or double-sided tapes for mounting the piezoelectric device to a printed circuit (“PC”) board. Such techniques offer some stability against g-forces, rotational and torsional forces, but simply are not acceptable for flexibly mounting piezoelectric transformers onto a PC board without also causing significant decline in the transformer performance.

However, these prior art mounting techniques are unacceptable because when a sufficient amount of shock or vibration is applied to the mounted piezoelectric device, the piezoelectric device becomes unattached from the PC board or the electrical contacts become fractured. This is due to the fact vibrational stresses are concentrated at the portions of the piezoelectric transformer where it is attached to the PC board, i.e. the electrodes. Piezoelectric devices also present a particular challenge to mount on a PC board because it is desirous to mount the piezoelectric device with as few connections as possible and as near to nodes of vibration as possible. This is because a larger number of connections and connections away from the nodes of vibration of the piezoelectric element hinder the natural vibration of the piezoelectric element and, therefore, causes a decrease in the pressure increase ratio and the conversion efficiency of the piezoelectric transformer.

In one such prior art mounting technique described in U.S. Pat. No. 6,037,705 ('705 patent), a conductive adhesive is used to provide an electrical attachment from a PC board to a piezoelectric device. However, the '705 patent still requires the use of a resilient adhesive member to support and connect the piezoelectric transformer to a PC board. The present invention requires no separate resilient adhesive member to support and connect the piezoelectric transformer to a PC board.

Therefore, it would be advantageous to provide a simple and inexpensive method for flexibly mounting a piezoelectric device on a PC board with the fewest number of connections while still maintaining the ability to withstand high amounts of shock.

### SUMMARY OF THE INVENTION

The present invention provides a method of mounting a piezoelectric device having a plurality of piezoelectric mounting pads directly to a PC board having a plurality of PC board mounting pads. The method comprises the steps of applying first amounts of a conductive adhesive to each of one of the piezoelectric mounting pads and the PC board mounting pads, curing the first amounts of conductive adhesive, applying second amounts of a conductive adhesive to each the other of the PC board mounting pads and the piezoelectric mounting pads, placing the piezoelectric device on the PC board such that the PC board mounting pads and the piezoelectric mounting pads correspond to one another, and curing the second amounts of conductive adhesive in order to attach the piezoelectric device to the PC board solely with first amounts of conductive adhesive and the second amounts of conductive adhesive.

In another embodiment present invention provides a device comprising a PC board having a plurality of PC board mounting pads, a piezoelectric device having a plurality of piezoelectric mounting pads which correspond to the PC board mounting pads, the PC board and the piezoelectric device attached in a spaced relationship at corresponding PC board mounting pads and piezoelectric mounting pads solely by a conductive adhesive attachment. Each conductive adhesive attachment comprises a first amount of conductive adhesive attached to one of the piezoelectric mounting pad and the PC board mounting pad, the first amount of conductive adhesive determining a distance of the spaced relationship between the piezoelectric device and the PC board and a second amount of conductive adhesive for attaching the piezoelectric device to the PC board.

### BRIEF DESCRIPTION OF THE DRAWINGS

FIG. 1 is a perspective of a piezoelectric transformer in position to be mounted to a PC board according to an embodiment of the present invention;

FIG. 2 is a flow diagram of steps required to assemble a piezoelectric transformer to a PC board according to preferred embodiment of the present invention; and

FIG. 3 is a side plan view of a piezoelectric transformer assembled to a PC board according to a preferred embodiment of the present invention.

### DETAILED DESCRIPTION OF THE PREFERRED EMBODIMENT

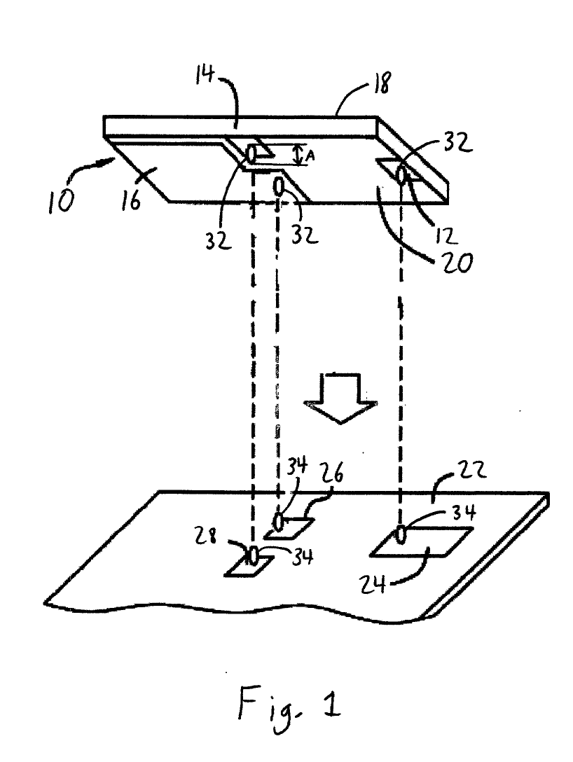

Referring now to the FIG. 1, there is shown a piezoelectric transformer 10 having a transformer high voltage output connected to a high voltage output mounting pad 12 and the transformer low voltage inputs connected to low voltage input mounting pads 14, 16. For certain applications, the present embodiment may also include a feedback tap mounting pad (not shown) which is connected to a feedback tap of the piezoelectric transformer 10. The piezoelectric transformer 10 may also be of the type which has a via or passage (not shown) which extends from a top side 18 of the piezoelectric transformer 10 to a bottom side 20 of the piezoelectric transformer 10.

In FIG. 1, the piezoelectric transformer 10 is shown detached from a PC board 22 but in position to be mounted to the PC board 22. The PC board 22 comprises conductive traces (not shown) which run between other circuitry elements (not shown) mounted to the PC board 22 and PC board mounting pads 24, 26, 28 for mounting the piezoelectric transformer 10.

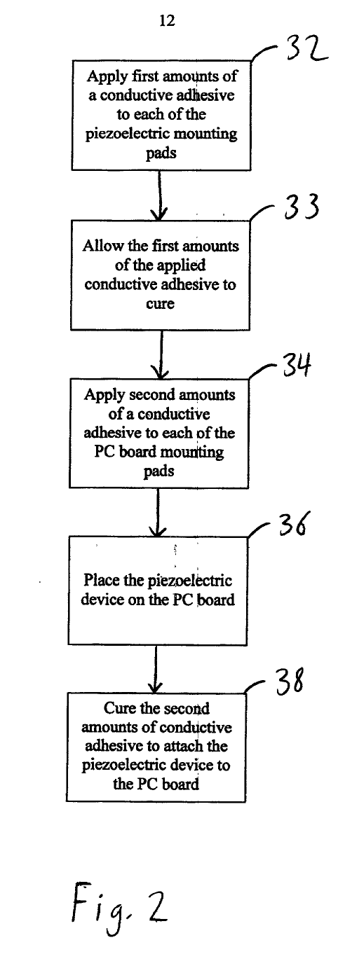

Referring to FIGS. 1 and 2, the piezoelectric transformer 10 and the PC board 22 are attached by, in step 30, applying a small amount of an electrically conductive adhesive 32 to each piezoelectric mounting pad 12. 14, 16 of the piezoelectric transformer 10. The conductive adhesive 36 preferably comprises a conductive filler, a binding agent arid additives. The conductive filler may comprise, for example, a silver powder, a gold powder, a copper powder, a nickel powder, an aluminum powder, carbon black, graphite or carbon fiber. The binder may comprise, for example, an acrylic resin, an epoxy resin, a vinyl resin, an acrylic-denatured polyurethane resin, a rubber-based resin or an epoxy polyamide resin. Further, the additive preferably contains a dispersing agent for enhancing filler dispersion, a lubricant for providing wear resistance or a conductive filler sedimentation preventive agent. Preferably the resistivity of the adhesive is very low, such as 0.0004 Ω/cm.

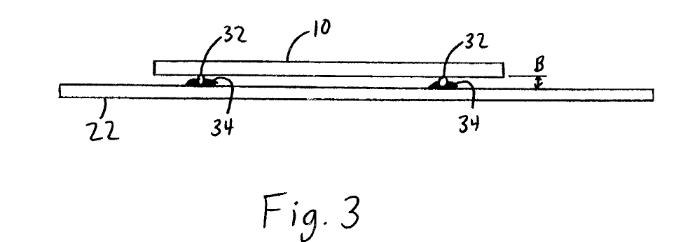

The amount of adhesive applied is selected to provide a “bump” of adhesive on each of the mounting pads 12, 14, 16. The “bump ” should extend from the piezoelectric transformer 10 a dimension A substantially equal to a dimension B (FIG. 3) that the piezoelectric transformer 10 will be offset from the PC board 22. For example, if it is desired to space the piezoelectric transformer 10 a dimension of 0.014″ from the PC board, the amount of adhesive is selected to provide a “bump” of adhesive which substantially extends 0.014″ from the plane of the piezoelectric transformer 10. Next, in step 34, a small amount of conductive adhesive 36 is applied to each of the PC board mounting pads 24, 26, 28.

Referring to FIGS. 2 and 3, in step 36 the piezoelectric transformer 10 is mounted on the PC board 22 such that the piezoelectric mounting pads 12, 14, 16 are aligned with the PC board mounting pads 24, 26, 28 while the adhesive on the PC board mounting pads 24, 26, 28 is uncured. By applying the piezoelectric transformer 10 to the uncured adhesive 36 of the PC board 22, the adhesive 36 of the PC board is deformed and surrounds the cured adhesive 32 of the piezoelectric transformer 10. Finally, in step 38, the adhesive of PC board mounting pads 24, 26, 28 is allowed to cure.

Preferably, the adhesives 32, 34 cure to a Shore A hardness of between 65 and 75. Most preferably, the adhesive is allowed to cure to a Shore A hardness of 70. At that hardness, adequate mechanical support is provided while minimizing mechanical damping. The harder the adhesive, the higher the damping of the device and the higher the tendency to fracture with temperature cycling, board flex, and accumulated exposure to the piezoelectric device's normal mechanical vibration. An adhesive that is too soft allows the piezoelectric transformer to move too far in response to large mechanical shocks and dampens the desired vibration in much the same way as a thick syrup would. A suitable conductive epoxy containing a silver powder and capable of curing to a Shore A hardness of 70 can be obtained from the Tracon of Bedford, Mass. and available under the name of TRA-DUCT 926K01. Next, in step 33, the adhesive 32 is allowed to cure. As a result, the adhesive not only forms a flexible attachment between the piezoelectric transformer 10 and the PC board 22, but also forms a conductive path between the piezoelectric mounting pads 12, 14, 16 and the PC board 24, 26, 28.

Referring to FIG. 3, the piezoelectric transformer 10 is shown attached to the PC board 22. In FIG. 3, adhesive 32 can be seen which cured on the piezoelectric mounting pads 12, 14, 16. Also adhesive 34 applied to PC board mounting pads 24, 26, 28 can be seen which were deformed by the adhesive 32 of the piezoelectric mounting pads 12, 14, 16 when the piezoelectric transformer 10 was brought into proximity with the PC board 22. It will be appreciated by viewing FIG. 3 that, as described above, the adhesive 32 determine the distance B that the piezoelectric transformer 10 is spaced away from the PC board 22.

It will be appreciated by one of ordinary skill in the art that the order of application of the adhesive could be reversed without departed from the scope of the present invention. More particularly described, the conductive adhesive 32 could be first applied to the PC board mounting pads 24, 26, 28 and allowed to cure. The piezoelectric mounting pads 12, 14, 16 could then be applied with the adhesive 34 and the piezoelectric transformer 10 placed onto the PC board 22. Finally, the adhesive 34 would be allowed to cure.

Operational tests performed on assembled piezoelectric transformers and PC boards, where the piezoelectric transformer has been flexibly mounted as described above, have indicated that the efficiency of a mounted piezoelectric transformer is reduced less than 5% from the efficiency of the non-mounted piezoelectric transformer. At the same time, the mount between the piezoelectric transformer the PC board is strong enough to withstand a shock of 50 g for 11 ms along three axes.

While the specific embodiment has been illustrated and described, numerous modifications come to mind without departing from the spirit of the invention. The scope of protection is only limited by the scope of the accompanying claims not the specific embodiment of those claims described above.

I claim:

1. A method of mounting a piezoelectric device having a plurality of piezoelectric mounting pads directly to a PC board having a plurality of PC board mounting pads, the method comprising the steps of:
applying first amounts of a conductive adhesive to each of the piezoelectric mounting pads;
curing the first amounts of conductive adhesive;
applying second amounts of a conductive adhesive to each of the PC board mounting pads;
placing the piezoelectric device on the PC board such that the PC board mounting pads and the piezoelectric mounting pads correspond to one another; and
curing the second amounts of conductive adhesive in order to attach the piezoelectric device to the PC board solely with first amounts of conductive adhesive and the second amounts of conductive adhesive.

2. The method of claim 1 wherein the first amounts of conductive adhesive and the second amounts of conductive adhesive each comprise a silver-filled epoxy resin.

3. The method of claim 2 wherein the conductive adhesive cures to a Shore A hardness of between 65 and 75.

4. The method of claim 1 wherein the conductive adhesive bond between the PC board mounting pad and the piezoelectric mounting pad can withstand a shock test of 50 g for 11 milliseconds along 3 axes without a significant fracturing of the bond.

5. The method of claim 1 wherein the conductive adhesive between the PC board mounting pad and the piezoelectric mounting pad has a resistivity no greater than 0.0004Ω/cm.

6. The method of claim 1 wherein the first selected amount of adhesive applied to the piezoelectric mounting pad maintains a distance between the piezoelectric device and the PC board of about 0.014″ or greater.

7. A device comprising:
a PC board having a plurality of PC board mounting pads;
a piezoelectric device having a plurality of piezoelectric mounting pads which correspond to the PC board mounting pads, the PC board and the piezoelectric device attached in a spaced relationship at corresponding PC board mounting pads and piezoelectric mounting pads solely by a conductive adhesive attachment, each conductive adhesive attachment comprising:
a first amount of conductive adhesive attached to the piezoelectric mounting pad, the first amount of conductive adhesive determining a distance of the spaced relationship between the piezoelectric device and the PC board; and
a second amount of conductive adhesive for attaching the piezoelectric device to the PC board.

8. The device of claim 7 wherein the first mount of adhesive and the second amount of adhesive are each a silver-filled epoxy resin.

9. The device of claim 8 wherein the silver-filled epoxy resin cures to a Shore A hardness of between 65 and 75.

10. The device of claim 7 wherein the device can withstand a shock of 50 g for 11 ms without significant fracture of the first or second amounts of conductive adhesive.

11. The device of claim 7 wherein the conductive adhesive has a resistivity no greater than 0.0004 Ω/cm.

12. The device of claim 7 wherein the spaced relationship between the piezoelectric device and the PC board is about 0.014″ or greater.

13. A method of mounting a piezoelectric device having a plurality of piezoelectric mounting pads directly to a PC board having a plurality of PC board mounting pads, the method comprising the steps of:
applying first amounts of a conductive adhesive to each of the PC board mounting pads;
curing the first amounts of conductive adhesive;
applying second amounts of a conductive adhesive to each of the piezoelectric mounting pads;
placing the piezoelectric device on the PC board such that the PC board mounting pads and the piezoelectric mounting pads correspond to one another; and
curing the second amounts of conductive adhesive in order to attach the piezoelectric device to the PC board solely with first amounts of conductive adhesive and the second amounts of conductive adhesive.

14. The method of claim 13 wherein the first amounts of conductive adhesive and the second amounts of conductive adhesive each comprise a silver-filled epoxy resin.

15. The method of claim 14 wherein the conductive adhesive cures to a Shore A hardness of between 65 and 75.

16. The method of claim 13 wherein the conductive adhesive bond between the PC board mounting pad and the piezoelectric mounting pad can withstand a shock test of 50 g for 11 milliseconds along 3 axes without a significant fracturing of the bond.

17. The method of claim 13 wherein the conductive adhesive between the PC board mounting pad and the piezoelectric mounting pad has a resistivity no greater than 0.0004 Ω/cm.

18. The method of claim 13 wherein the first selected amount of adhesive applied to the piezoelectric mounting pad maintains a distance between the piezoelectric device and the PC board of about 0.014″ or greater.

19. A device comprising:
a PC board having a plurality of PC board mounting pads;
a piezoelectric device having a plurality of piezoelectric mounting pads which correspond to the PC board mounting pads, the PC board and the piezoelectric device attached in a spaced relationship at corresponding PC board mounting pads and piezoelectric mounting pads solely by a conductive adhesive attachment, each conductive adhesive attachment comprising:
a first amount of conductive adhesive attached to the PC board mounting pad, the first amount of conductive adhesive determining a distance of the spaced relationship between the piezoelectric device and the PC board; and
a second amount of conductive adhesive for attaching the piezoelectric device to the PC board.

20. The device of claim 19 wherein the first mount of adhesive and the second amount of adhesive are each a silver-filled epoxy resin.

21. The device of claim 20 wherein the silver-filled epoxy resin cures to a Shore A hardness of between 65 and 75.

22. The device of claim 19 wherein the device can withstand a shock of 50 g for 11 ms without significant fracture of the first or second amounts of conductive adhesive.

23. The device of claim 19 wherein the conductive adhesive has a resistivity no greater than 0.0004 Ω/cm.

24. The device of claim 19 wherein the spaced relationship between the piezoelectric device and the PC board is about 0.0144″ or greater.
